(19) United States
(12) Patent Application Publication
(10) Pub. No.: US 2020/0266278 A1
(43) Pub. Date: Aug. 20, 2020

(54) GATE STRUCTURES RESISTANT TO VOLTAGE BREAKDOWN

(71) Applicant: INTEL CORPORATION, Santa Clara, CA (US)

(72) Inventors: Marko RADOSAVLJEVIC, Portland, OR (US); Sansaptak DASGUPTA, Hillsboro, OR (US); Han Wui THEN, Portland, OR (US); Paul B. FISCHER, Portland, OR (US); Walid M. HAFEZ, Portland, OR (US)

(73) Assignee: INTEL CORPORATION, Santa Clara, CA (US)

(21) Appl. No.: 16/279,150

(22) Filed: Feb. 19, 2019

(51) Int. Cl. H01L 29/40; H01L 29/20; H01L 29/205; H01L 29/423; H01L 29/778; H01L 21/765; H01L 21/28; H01L 29/66; H01L 23/66

(52) U.S. Cl. CPC H01L 29/402; H01L 29/2003; H01L 29/205; H01L 29/42376; H01L 23/66; H01L 21/765; H01L 21/28264; H01L 29/401; H01L 29/66462; H01L 29/7787

(57) ABSTRACT

A semiconductor device structure having a “T-shaped” gate structure is described. A narrower first portion supports high frequency processes (e.g., gigahertz wireless communications). A second portion of the gate structure has a second width greater than the first width. Lateral extensions (sometimes referred to as “field plates), thinner and wider than the second portion, extend from the second portion. This combination of a gate structure having a narrow first portion and a wider second portion improves the performance of the semiconductor device in applications that involve both high frequency and high power consumption.

### BACKGROUND

Semiconductor devices can be used in applications that regulate voltage and/or power. For example, power supply modules between a computing device and a power source (e.g., an electrical socket in a wall) often have semiconductor devices and other components that reduce the voltage of the power source to a voltage level usable by the computing device. In some cases, a voltage must be reduced twice—once by the power supply and once again by voltage regulators in the computing device itself. At each stage of regulation, power is lost thus reducing the electrical efficiency of the system.

### BRIEF DESCRIPTION OF THE DRAWINGS

FIGS. 1A-1I illustrate example cross-sectional views taken perpendicular to a gate structure at various stages of fabrication of an integrated circuit structure that includes a gate structure having a first portion narrower than a second portion, the second portion including lateral extensions therefrom, in accordance with an embodiment of the present disclosure.

FIG. 2 illustrates a computing system including one or more of the integrated circuit structures as variously described herein, in accordance with an embodiment of the present disclosure.

The figures depict various embodiments of the present disclosure for purposes of illustration only. Numerous variations, configurations, and other embodiments will be apparent from the following detailed discussion. Furthermore, as will be appreciated, the figures are not necessarily drawn to scale or intended to limit the described embodiments to the specific configurations shown. For instance, while some figures generally indicate straight lines, right angles, and smooth surfaces, an actual implementation of the disclosed techniques may have less than perfect straight lines and right angles, and some features may have surface topography or otherwise be non-smooth, given real-world limitations of fabrication processes. In short, the figures are provided merely to show example structures.

### DETAILED DESCRIPTION

Semiconductor devices and corresponding fabrication methods are disclosed. In some embodiments, a semiconductor device structure having a “T-shaped” gate structure is described. A first portion of the gate structure has a first width, where the first portion is disposed between a source region and a drain region. The narrower first width is configured and dimensioned consistent with nanometer-scale gate process nodes to support high frequency computing operations (e.g., gigahertz wireless communications). A second portion of the gate structure is disposed over, and in some cases on and/or in contact with the first portion, where the second portion has a second width greater than the first width. Lateral extensions (sometimes referred to herein as “field plates” or “wings” or “extensions”), vertically thinner than the second portion in some embodiments, extend laterally from the second portion. The presence of the second portion and its associated lateral extensions increases the cross-sectional area and volume of a gate structure. This combination of a gate structure having a narrow first portion and a wider second portion with field plates can improve the performance of the semiconductor device in applications that involve high power, high frequency, and/or high power operations.

General Overview

In some technological applications, semiconductor devices operate at one or more of high frequencies (e.g., in the gigahertz (GHz) range), high power (e.g., greater than 1 Watt/millimeter (W/mm)), and/or high voltage (e.g., greater than 20 Volts (V), greater than 100 V, or greater than 500 V). These conditions cause the semiconductor device to experience strong electromagnetic fields, high currents, and/or higher temperatures (among other effects), than those experienced under less demanding operating conditions. For example, semiconductor devices used for power and/or voltage regulation (e.g., such as in power supply devices and/or power/voltage controllers) generally operate at higher voltages and higher currents than, for example, integrated logic or memory circuits used within a computing device for logic operations. These high frequency, high power, and/or high voltage conditions can adversely impact reliable operation for some configurations of semiconductor devices. For example, semiconductor devices having a bandgap of less than 2 electron Volts (eV) (e.g., a bandgap of 1.1 eV, as in the case of silicon-based semiconductor devices) can experience voltage breakdown under high voltage conditions.

In some cases, high electrical fields in these types of applications can be managed by including “field plates” within an integrated circuit. These conductive elements can aid in the distribution of electrical fields more uniformly and/or more broadly, reducing the likelihood of localized voltage breakdown. Field plates are traditionally located within an interconnect level of an integrated circuit that is above a device level. While this can increase the convenience of fabrication and reduce the capacitance penalty of including this additional conductive structure in an integrated circuit, locating a field plate away from a gate structure also reduces the effectiveness of the field plate in reducing conditions that may lead to voltage breakdown. These field plates may also be more intuitively referred to as “wings” or “extensions”, as technically speaking, they are not field plates given the traditional interconnect-based meaning of that phrase, as will be appreciated in light of this disclosure.

In some cases, managing voltage breakdown includes semiconductor devices having band gaps greater than 2 eV or even greater than 3 eV. When used in high frequency, high power, and/or high voltage applications, the performance and reliability of the device as a whole can be improved using structures (e.g., that include a channel region) having a higher bandgap because higher electromagnetic fields and/or power levels can be sustained in the structures without voltage breakdown. While some high band gap materials (e.g., greater than 2 eV, greater than 3 eV) have lower charge carrier mobilities than silicon, thus slowing the operational speed of the device, gallium nitride (GaN) semiconductor devices are an exception. Charge carrier mobility in GaN device structures is approximately the same (or in some cases slightly higher) than that of silicon semiconductor devices. Because of this, gallium nitride devices can have similar or even better performance than silicon-based semiconductor device structures for a given device size (e.g., as measured by gate length).

High bandgap semiconductor devices, such as gallium nitride, may also be advantageously used in technological applications that are high frequency (e.g. gigahertz), high power, and/or high power, such as power amplifiers in radio frequency communications. This combination of application conditions, however, can be challenging to integrate into a single semiconductor device. This is because some of the physical features useful for high frequency communications are not easily compatible with the physical features useful for high power applications. For example, high frequency applications are generally best served with semiconductor devices having a short gate length (e.g., a lateral distance of a semiconductor body between opposing source and drain regions). This is because generally shorter gate lengths are better able to support faster devices (e.g., operating at a high frequency), and thus better support higher frequency data transmissions such as found in gigahertz mobile communications. High power technological applications, however, may benefit from gates that have a relatively high volume. Gate structures having a high volume may be more able to sustain high power through a given gate and may be more able to maintain a uniform voltage over a length of a gate structure that may, in the case of a “tri-gate” or finFET transistor, be continuous over many fins.

Thus, in accordance with some embodiments of the present disclosure, techniques are described for fabricating semiconductor devices having a short gate length, a high gate volume, and that integrate lateral wings or extensions (e.g., “field plates”) within a gate structure itself. This configuration can be accomplished by forming a T-shaped gate structure in which a lower portion disposed over a semiconductor body and between a source region and a drain region is narrower than an upper portion above the source/drain regions. The upper portion is configured to have field plates extending laterally therefrom. In this way, the lower portion can provide short gate lengths preferable for high frequency (high switching speed) operation, the upper portion can add volume to the gate structure to support high power operation, and the field plates can reduce electromagnetic field concentration to reduce the likelihood of voltage breakdown. In some embodiments, devices having this gate structure can include a semiconductor body under the gate structure that is made from a III-V semiconductor material (e.g., GaN) with a band gap greater than 2 eV or greater than 3 eV, further reducing the likelihood of voltage breakdown during high voltage operation. Furthermore, some of the devices described herein can improve the electrical efficiency of power supply systems by enabling a single step from input voltage to application voltage that might other require multiple steps.

Architecture and Methodology

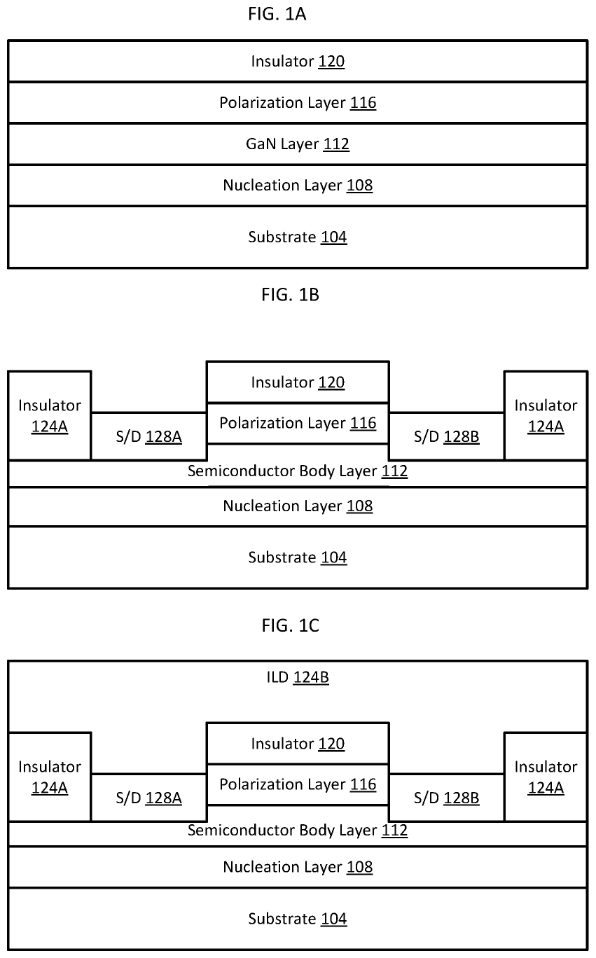

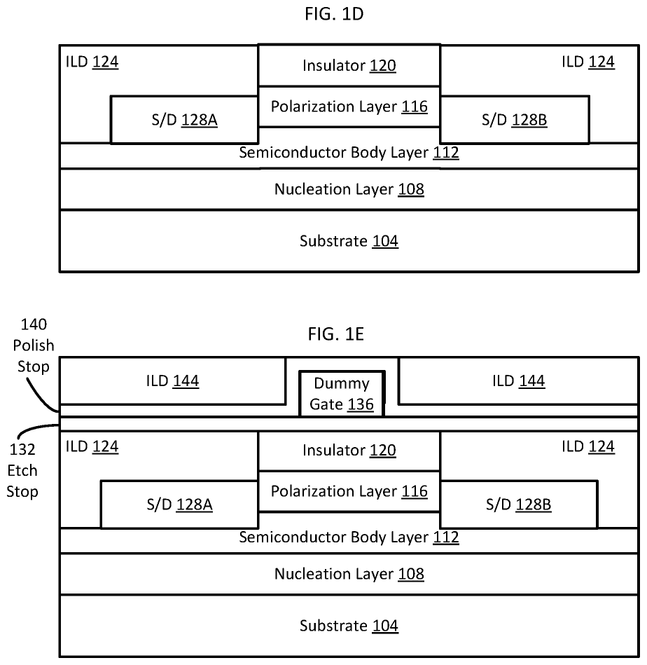

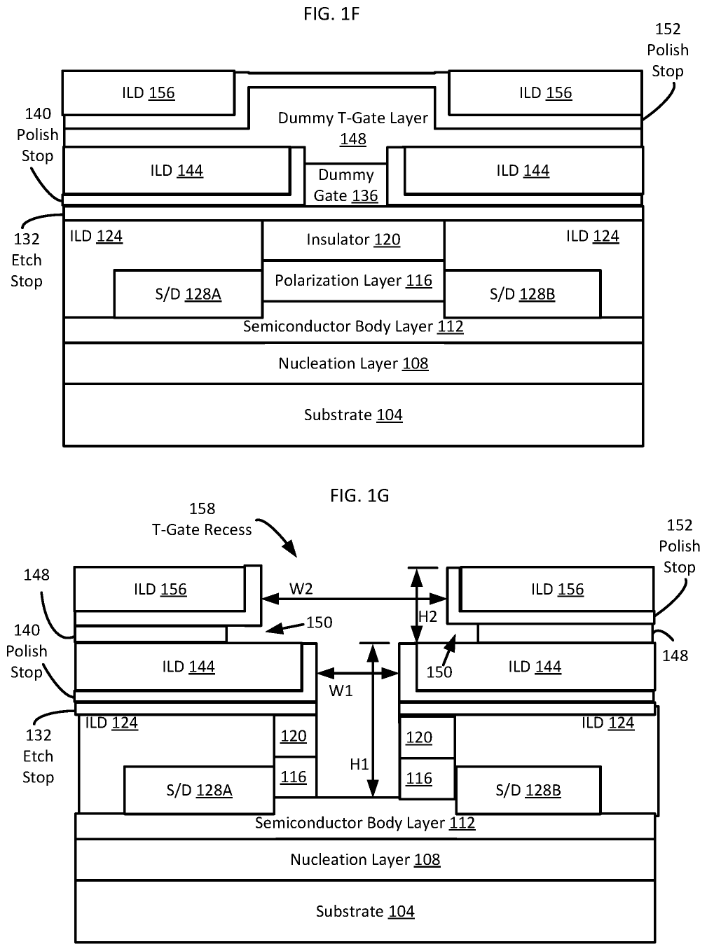

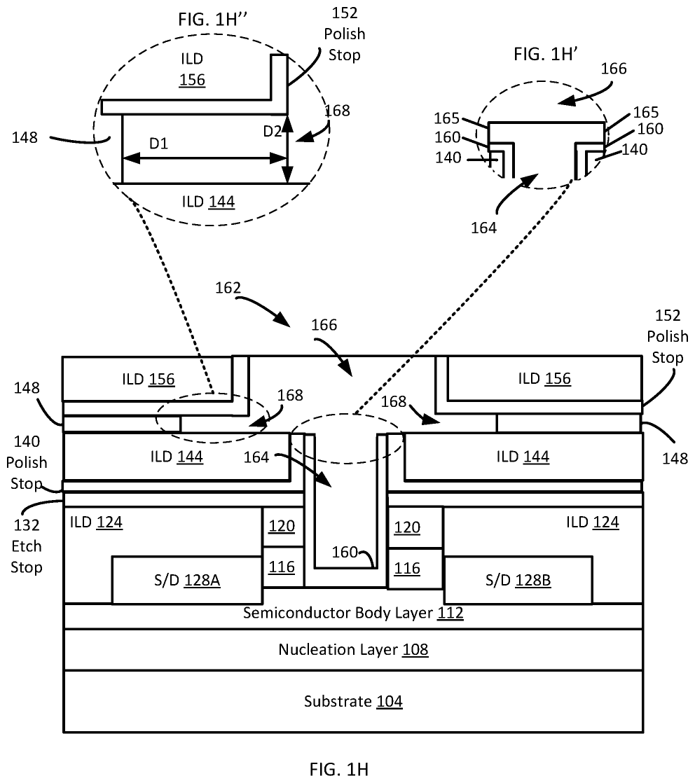

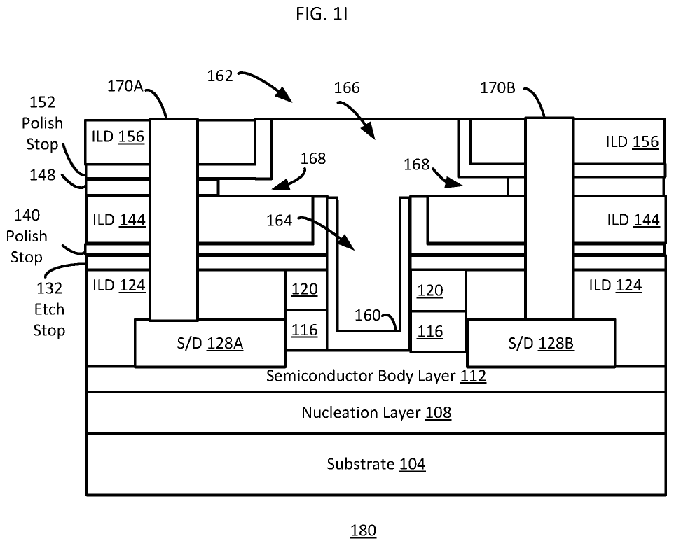

FIGS. 1A-1I illustrate various stages of fabrication of an example device 180 (shown in FIG. 1I) that can support one or more of high frequency (e.g., gigahertz (GHz)) operation, high power operation (e.g., greater than 1 Watt/millimeter (W/mm)), and/or high voltage (e.g., as described above. These example cross-sectional views are taken perpendicular to a gate structure.

Turning first to FIG. 1A, fabrication of an example device begins by providing a substrate 104, and successively forming on the substrate 104 a nucleation layer 108, a semiconductor body layer 112 (in this example GaN), a polarization layer 116, and an insulator layer 120.

In some examples the substrate 104 can include silicon oriented so as to expose crystallographic planes having a Miller Index of (111). (111) silicon presents planes with atoms in a hexagonal configuration (unit cell), which can match the crystal structure of various semiconductor compounds that may be useful for forming a semiconductor body in some embodiments of the present disclosure. This orientation of silicon thus lends itself to the epitaxial formation of some materials. For example, the (111) planes of a silicon substrate are epitaxially compatible (e.g., the lattice parameters are less than or equal to 17% of one another) with the gallium nitride crystal, which has the hexagonal Wurtzite structure. Thus, because the lattice parameters of both the (111) silicon and GaN are epitaxially compatible and the crystallographic organization of (111) silicon and GaN are compatible, GaN can be formed on a (111) silicon substrate. As will be appreciated, the high band gap of GaN (˜3.4 eV) can be beneficial for reducing the likelihood of voltage breakdown in high voltage/high power applications.

Other substrates 104 may be used in other embodiments, particularly when selecting the substrate 104 to be epitaxially and crystallographically compatible with a material selected for a semiconductor body (that will include the channel region in a completed semiconductor device). For example, some embodiments may include a bulk Si substrate (e.g., a bulk Si wafer), a Si on insulator (SOI) structure where an insulator/dielectric material (e.g., an oxide material, such as silicon dioxide) is sandwiched between two Si layers (e.g., in a buried oxide (BOX) structure), or any other suitable starting substrate where the top layer includes Si. In some embodiments, the substrate may be doped with any suitable n-type and/or p-type dopant at a dopant concentration in the range of 1E16 to 1E22 atoms per cubic cm, for example. For instance, the Si of the substrate may be p-type doped using a suitable acceptor (e.g., boron) or n-type doped using a suitable donor (e.g., phosphorous, arsenic) with a doping concentration of at least 1E16 atoms per cubic cm. However, in some embodiments, the substrate may be undoped/intrinsic or relatively minimally doped (such as including a dopant concentration of less than 1E16 atoms per cubic cm), for example. In general, although the substrate is referred to herein as a Si substrate, in some embodiments, it may essentially consist of Si, while in other embodiments, the substrate may primarily include Si but may also include other material (e.g., dopant at a given concentration). Also note that the substrate may include relatively high quality or device quality monocrystalline Si that provides a suitable template/seeding surface from which other monocrystalline semiconductor material features and layers can be formed. Therefore, unless otherwise explicitly stated, a Si substrate as described herein is not intended to be limited to a substrate that only includes Si. Any of these preceding examples of substrates can be used or adapted to facilitate growth of GaN or other material that supports high frequency, high power technological applications, as indicated above.

As will be appreciated, in some embodiments, the substrate may include a surface crystalline orientation described by a Miller index of (100), (110), or (111), or its equivalents, as will be apparent in light of this disclosure. As indicated above, crystalline orientation of a substrate can be selected to be crystallographically and/or epitaxially favorable to the formation of other layers on the substrate 104.

Although substrate 104, in this example embodiment, is shown as having a thickness (dimension in the Y-axis direction) similar to other layers in the figures for ease of illustration, in some instances, the substrate may be relatively much thicker than the other layers, such as having a thickness in the range of 1 to 950 microns (or in the sub-range of 20 to 800 microns), for example, or any other suitable thickness value or range as will be apparent in light of this disclosure. In some embodiments, the substrate may include a multilayer structure including two or more distinct layers (that may or may not be compositionally different). In some embodiments, the substrate may include grading (e.g., increasing and/or decreasing) of one or more material concentrations throughout at least a portion of the substrate. In some embodiments, the substrate may be used for one or more other IC devices, such as various diodes (e.g., light-emitting diodes (LEDs) or laser diodes), various transistors (e.g., MOSFETs or TFETs), various capacitors (e.g., MOSCAPs), various microelectromechanical systems (MEMS), various nanoelectromechanical systems (NEMS), various radio frequency (RF) devices, various sensors, or any other suitable semiconductor or IC devices, depending on the end use or target application. Accordingly, in some embodiments, the structures described herein may be included in a system-on-chip (SoC) application, as will be apparent in light of this disclosure.

In some examples, a nucleation layer 108 is formed on the substrate 104. In some examples, the nucleation layer 108 can improve the epitaxial formation of subsequently formed material structures including materials used for a semiconductor body. In the specific example of a semiconductor body formed from GaN and on a substrate 104 of (111) silicon, the nucleation layer 108 can be aluminum nitride (AlN). It will be appreciated that the nucleation layer can be selected in part based on the composition, lattice parameter and crystallographic orientation of the substrate 104 and the semiconductor body layer 112. The nucleation layer 108 can be formed by any suitable technique, some of which include physical vapor deposition (PVD); chemical vapor deposition (CVD); atomic layer deposition (ALD); and/or combinations thereof.

In some examples a semiconductor body layer 112 is formed on the nucleation layer, and can be used to form a semiconductor body that includes a channel region of a semiconductor device. As indicated above, GaN is one example material that can be used for the semiconductor body layer 112 and is particularly compatible with a nucleation layer 108 formed from AlN. Other examples of materials that can be used to form the semiconductor body layer 112 include, but are not limited to gallium and nitrogen alloyed and/or compounded with other Group III element alloys, for example indium aluminum gallium nitride (InAlGaN).

As with the nucleation layer 108, the semiconductor body layer 112 can be formed by any suitable technique, some of which include physical vapor deposition (PVD); sputtering; chemical vapor deposition (CVD); atomic layer deposition (ALD); and/or combinations thereof.

In some examples the polarization layer 116 between the source/drain regions and the gate induces a two-dimensional electron gas (2DEG) in the GaN layer to form a channel underneath the gate. In general, the polarization layer includes a material having a higher bandgap than the material of the underlying semiconductor body layer 112, to form the 2DEG configuration, sometimes referred to as polarization doping. For instance, in some embodiments, the semiconductor body layer 112 includes GaN and the polarization layer includes AlN and/or AlGaN, for example. In other embodiments, the semiconductor body layer 112 may include AlGaN and the polarization layer may include GaN, AlN, and/or AlGaN, for example. In some embodiments, the polarization layer may have a multilayer structure including multiple III-V materials. In some such embodiments, one of the layers in the multilayer structure may be present to further increase carrier mobility in the transistor channel region and/or to improve compatibility (e.g., density of interface traps) between polarization layer and overlying layers (such as the gate dielectric layer), for example. The polarization layer may or may not include grading (e.g., increasing and/or decreasing) the content of one or more materials in at least a portion of the layer. The thickness (the dimension in the Y direction) of the polarization layer will vary from one embodiment to the next, but in some example cases is in the range of 0.1 to 100 nm (e.g., 0.5 to 5 nm), but any suitable thickness can be used. Other embodiments may have other non-2DEG channel configurations. Numerous channel configurations will be apparent in light of this disclosure and the present disclosure is not intended to be limited to any particular configuration.

An insulator layer 120 can be formed on the polarization layer 116. In some examples the insulator layer 120 can include, for instance, nitrides (e.g., Si₃N₄), oxides (e.g. SiO₂, Al₂O₃), oxynitrides (e.g., SiOₓN_{y}), carbides (e.g., SiC), oxycarbides, polymers, silanes, siloxanes, or other suitable insulator materials. In some embodiments, the insulator layers in this example and the subsequently described examples can be implemented with ultra-low-k insulator materials, low-k dielectric materials, or high-k dielectric materials depending on the application. Example low-k and ultra-low-k dielectric materials include porous silicon dioxide, carbon doped oxide (CDO), organic polymers such as perfluorocyclobutane or polytetrafluoroethylene, fluorosilicate glass (FSG), and organosilicates such as silsesquioxane, siloxane, or organosilicate glass. Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

Techniques for forming insulator layer 120 can be any of a wide range of suitable deposition techniques, including but not necessarily limited to: physical vapor deposition (PVD); chemical vapor deposition (CVD); spin coating/spin-on deposition (SOD); atomic layer deposition (ALD); and/or a combination of any of the aforementioned. Other suitable configurations, materials, deposition techniques, and/or thicknesses for these layers will be apparent in light of this disclosure.

FIG. 1B illustrates formation of source and drain (“S/D”) regions 128A, 128B. In some examples, patterning techniques (e.g., using wet etches, dry etches, photolithographic masks) can be used to remove portions of the insulator layer 120, the polarization layer 116, and optionally some of the semiconductor body layer 112. In some examples, insulator layers 124A (described below) can be patterned so that a gap exists between the insulator layers 124A and the polarization layer 116. For example, the layers 124A can be formed as part of a shallow trench isolation (STI) process that exposes (or leaves exposed) portions of the semiconductor body layer 112. In some examples, this can be followed by epitaxial formation of the source/drain regions 128A, 128B on the exposed portions of the semiconductor body layer 112 in a “self-aligned” formation technique. Other techniques are also possible for formation of the source/drain regions 128A, 128B.

In the example shown, the source/drain regions 128A, 128B are n-doped indium gallium nitride (InGaN) epitaxially formed on the semiconductor body layer 112. The composition of InGaN source/drain regions 128A, 128B can be adjusted so that the relative proportions of indium to gallium can go from 100% In and 0% Ga (to form InN) to 0% In and 100 Ga (to form GaN). It will be appreciated that other materials may be used for the source/drain regions. In some examples, source/drain 128A, 128B materials can be selected to have a smaller band gap that that in the semiconductor body layer 112 that includes a channel region.

In some embodiments, the S/D regions may be formed one polarity at a time, such as performing processing for one of n-type and p-type S/D regions, and then performing processing for the other of the n-type and p-type S/D regions. In some embodiments, the S/D regions may include any suitable material, such as monocrystalline group IV and/or group III-V semiconductor material and/or any other suitable semiconductor material, as will be apparent in light of this disclosure. In some embodiments, the S/D regions corresponding to a given semiconductor body (i.e., the region between the S/D regions) may include the same group of semiconductor material as what is included in the semiconductor body, such that if the given semiconductor body includes group IV semiconductor material, the corresponding S/D regions may also include group IV semiconductor material (whether the same IV material or different); however, the present disclosure is not intended to be so limited. In some embodiments, the S/D regions may include any suitable doping scheme, such as including suitable n-type and/or p-type dopant (e.g., in a concentration in the range of 1E16 to 1E22 atoms per cubic cm). In some examples, source/drain regions 128A, 128B doping concentrations can be in the upper ranges of doping concentration (e.g., 1E20, 1E20, 1E22 atoms per cubic cm). Example dopants can include silicon and germanium, among others. However, in some embodiments, at least one S/D region may be undoped/intrinsic or relatively minimally doped, such as including a dopant concentration of less than 1E16 atoms per cubic cm, for example.

To provide some example configurations, in embodiments where corresponding S/D regions on either side of a given channel region are to be used for a MOSFET device, the S/D regions may include the same type of dopants (e.g., where both are p-type doped or both are n-type doped). Specifically, for an n-MOS device, the included S/D regions include semiconductor material that is n-type doped, and for a p-MOS device, the included S/D regions include semiconductor material that is p-type doped, in some embodiments. Whereas for a TFET device, the S/D regions for a given channel region may be oppositely doped, such that one is p-type doped and the other is n-type doped, in some embodiments.

The insulator layers 124A can be composed of any of the materials indicated above in the context of the insulator layer 120, and similarly formed by any of the processes used for the insulator layer 120. That is, a layer composed of an electrical insulator (e.g., silicon dioxide) can be formed (e.g., by spin coating, CVD, PVD, ALD) on exposed surfaces of the semiconductor body layer 112 and then patterned, as described above, so that gaps are present to receive source/drain regions 128A, 128B. In other examples, the source/drain regions 128A, 128B are formed first and then followed by formation of the insulator layers 124A.

FIG. 1C shows formation of interlayer dielectric (ILD) 124B. ILD 124B can be formed from any of the materials and processes indicated above for insulator 120 and/or insulator layer 124A. In some cases, the layers 124A and 124B will have an interface between them. However, in some cases these layers will not have a clearly detectable interface. For the convenience of depiction, FIGS. 1D-1I refer to both layers 124A and 124 B simply as layer 124. As shown in FIG. 1D, ILD 124 is partially removed so as to expose the insulator layer 120. As shown, the removal process planarizes the ILD 124 so as to be coplanar with the insulator 120. In some examples, this partial removal can be accomplished using any suitable technique including chemical-mechanical planarization/polishing (CMP) processes, for example.

Turning now to FIG. 1E, an etch stop layer 132 is formed on the coplanar surfaces of the ILD 124 and the insulator 120. As will be appreciated, the etch stop layer 132 provides a surface resistant to a subsequently applied wet or dry etch. That is, the etch stop layer 132 is composed to be etched at a slower rate when exposed to a given etchant (whether a wet etch or dry etch) than the overlying materials. The utility of the etch stop layer 132 will be understood upon the description of processes in the context of FIGS. 1F-1I. In some examples, the etch stop layer 132 can be formed from any suitable material, such as silicon nitride, silicon carbide, among others. Example techniques that can be used to form the etch stop layer 132 include, but are not limited to, CVD, PVD, ALD, sputtering, among others.

A “dummy gate” electrode 136 is formed on the etch stop layer 132. As will be appreciated, this layer is referred to as a “dummy” gate electrode in the sense that it can be removed and replaced in a subsequent replacement metal gate (“RMG”) process in some embodiments. Example dummy gate electrode 136 materials include, for instance, polycrystalline silicon, although any suitable dummy/sacrificial gate dielectric and/or electrode materials can be used. As will be appreciated, the dimensions of the gate materials will vary from one embodiment to the next and can be configured as desired, depending on factors such as the desired device performance attributes, device size, and gate isolation.

A polish stop layer 140 can then be formed on the etch stop layer 132 and on (and/or over) the dummy gate 136. The polish stop layer 140 performs a similar function to the etch stop layer 132, providing a barrier to prevent over polishing that would otherwise remove layers below the polish stop layer 140. In some examples, the polish stop layer 140 can be formed from silicon nitride, although other materials can be used (e.g., silicon carbide). Example techniques that can be used to form the etch stop layer 132 include, but are not limited to, sputtering, physical vapor deposition (PVD), plasma assisted chemical vapor deposition, chemical vapor deposition (CVD), atomic layer deposition (ALD), MOCVD, MBE, among others.

ILD layer 144 can then be formed over the polish stop layer 140 and then subsequently partially removed (e.g., by CMP) to as to expose the salient portion of the polish stop layer 140 over the dummy gate electrode 136. This configuration is illustrated in FIG. 1E. Example techniques that can be used to form the ILD layer 144 include, but are not limited to, sputtering, physical vapor deposition (PVD), plasma assisted chemical vapor deposition, chemical vapor deposition (CVD), spin coating, atomic layer deposition (ALD), MOCVD, MBE, among others.

The exposed portion of the polish stop layer 140 over the dummy gate electrode 136 can then be removed using an etch (e.g., a “dry” etch), thus exposing the dummy gate 136. In some examples, the etch used is selective to the polish stop layer 140 material, removing ILD 144 at a rate that is slower (e.g., 2 times slower, 3 times slower, or more) than the removal rate of the polish stop layer 140 material. In some examples, such as the one shown in FIG. 1F, some of the dummy gate electrode 136 is also removed in this process, recessing the exposed surface of the dummy gate electrode 136 relative to the “top” surface of ILD layer 144 (e.g., the surface opposite that of the etch stop layer 132). This need not be the case, however, and in other examples the dummy gate electrode 136 will be closer to the top surface of the ILD layer 144 (e.g., coplanar or nearly coplanar) than the example shown.

With continued reference to FIG. 1F, a dummy T-gate electrode layer 148 is formed on the dummy gate electrode 136 and on (and/or over) at least some of the ILD layer 144. Patterning techniques (e.g., masking and etching) can be used so that a salient portion of the dummy T-gate electrode layer 148 over the dummy gate electrode 136 is thicker that some or all of the portions extending over ILD layers 144. After forming the dummy T-gate electrode layer 148, a polish stop layer 152 is formed over the dummy T-gate electrode layer 148. ILD layer 156 is then formed on the polish stop layer 152 and polished so as to expose the portion of the polish stop layer 152 over the salient portion of the dummy T-gate electrode layer 148. Formation of the polish stop layer 152, formation of the ILD layer 156, and exposure of the salient portion of the dummy T-gate electrode layer 148 can be accomplished using any of the techniques described above for analogous layers (e.g., sputtering, CVD, PVD, ALD, MOCVD, spin coating, polishing, patterning, and combinations thereof).

As shown in FIG. 1G, the exposed portion of the polish stop layer 152 can be removed (e.g., via a dry etch) to expose a surface of the dummy T-gate electrode layer 148. As will be recalled, the dummy T-gate electrode layer 148 and the dummy gate electrode layer 136 are formed from materials that can be selectively removed by etching (“selective etching”) that does not remove other components of the architecture shown in the figure or removes them at a significantly slower rate than the intended target of the etch. For example, when formed from polycrystalline silicon, the dummy T-gate electrode layer 148 and the dummy gate electrode layer 136 can be selectively removed by exposure to some etch chemistries that do not remove the various etch stop and polish stop layers.

It will also be noted that in some of these examples the wet etch can be isotropic, and thus can remove portions of the dummy T-gate electrode layer 148 between ILD layer 144 and polish stop layer 152, thus forming cavities 150. As is explained below, these cavities 150 will ultimately be filled with gate electrode material, thus forming “field plates” or “wings” or “extensions” in an upper portion of a gate that increase a volume of a gate electrode structure while maintaining narrow gate lengths.

A directional etch (e.g., ion milling, plasma etching) can be used to remove portions of the polish etch stop layer 140, the etch stop layer 132, insulator 120, and polarization layer 116. It will be noted that the use of a directional etch enables removal of primarily those portions of the polish etch stop layer 140, the etch stop layer 132, insulator 120, and polarization layer 116 left exposed by removal of a preceding layer. Because the effectiveness of the etch is partially a function of a component of slope of the surface that is orthogonal to the etch direction, surfaces parallel to the direction of the etch of removed at a significantly slower rate (e.g., at least 2 times, at least 3 times, or even slower) than those that are (more) perpendicular to the etch direction.

Removal of the various layers described above thus forms a T-gate electrode recess 158, as shown in FIG. 1G. The lower (first) portion of the recess 158 has a first width W1 defined by opposing exposed surfaces of layers 116, 120, 132, and 140. This lower portion extends vertically from an exposed surface of the semiconductor body layer 112 to an upper surface of ILD 144. This dimension is indicated as H1 in FIG. 1G. An upper (second) portion of the recess 158 has a width W2 defined by opposing exposed surfaces of polish stop layer 152. The upper portion extends vertically from exposed (top) surfaces of ILD 144 to exposed (top) surfaces of ILD 156. This dimension is indicated as H2 in FIG. 1G. It will be appreciated that the widths W1, W2, and heights H1, H2 described above will ultimately correspond to an electrode structure formed in the recess 158 and that these dimensions are equally applicable to that electrode structure (described below). Dimensions of the cavities 150 are described in more detail below in the context of the field plates formed therein.

Formation of a gate electrode structure in the T-gate electrode recess 158 begins by first forming a gate dielectric layer 160 in a lower portion of the T-gate electrode recess 158. This lower portion can be defined as the portion of the recess 158 between exposed surfaces of the semiconductor body layer 112 and the ILD layers 144. It will be appreciated than a top or upper portion of the T-gate electrode recess 158 is between the exposed (top) surface of the ILD layer 144 and the exposed (top) surface of the ILD layers 156. These denominations and boundaries are for convenience of reference.

Examples of the gate dielectric layer 160 can include a multilayer structure of two or more material layers, for example. For instance, in some embodiments, a multilayer gate dielectric may be employed to provide a more gradual electric transition from the channel region within a semiconductor body to the gate electrode, for example. In some embodiments, gate dielectric and/or gate electrode may include grading (e.g., increasing and/or decreasing) the content/concentration of one or more materials in at least a portion of the feature(s). The gate dielectric may be, for example, any suitable gate dielectric material(s) such as silicon dioxide or high-k gate dielectric materials. Examples of high-k gate dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used. Further, the gate electrodes may comprise a wide range of suitable metals or metal alloys, such as aluminum, tungsten, titanium, tantalum, copper, titanium nitride, or tantalum nitride, for example, or other suitable materials in light of the present disclosure. One or more additional layers may also be present in the final gate stack, in some embodiments, such as one or more relatively high or low work function layers and/or other suitable layers, for example. The gate structure (including the gate dielectric layer(s) and gate electrode layer(s) can be formed via any suitable process, including but not limited to sputtering, physical vapor deposition (PVD), plasma assisted chemical vapor deposition, chemical vapor deposition (CVD), atomic layer deposition (ALD), MOCVD, MBE, among others.

A gate electrode material can then be formed in the T-gate electrode recess 158 and within the gate dielectric layer 160, thus forming a lower (first) portion 164 of a gate electrode structure 162 (which includes both the gate electrode material and the gate dielectric layer(s) 160). Continued deposition of the gate electrode material in the recess 158 also forms an upper (second) portion 166 of the gate electrode structure 162 and fills cavities 150 shown in FIG. 1G so as to form field plates 168 that extend laterally from the upper portion 166 of the gate electrode structure 162. The gate electrode material may comprise a wide range of suitable metals or metal alloys, such as aluminum, tungsten, titanium, tantalum, copper, titanium nitride, or tantalum nitride, for example, or other suitable materials in light of the present disclosure. One or more additional layers may also be present in the final gate stack, in some embodiments, such as one or more relatively high or low work function layers and/or other suitable layers, for example. The gate structure 162 (including the gate dielectric layer(s) 160 and lower 164 and upper 166 gate electrode portions can be formed via any suitable process, including but not limited to sputtering, physical vapor deposition (PVD), plasma assisted chemical vapor deposition, chemical vapor deposition (CVD), atomic layer deposition (ALD), MOCVD, MBE, among others. Numerous different gate stack configurations will be apparent in light of this disclosure

Additional details of some embodiments of the gate electrode structure 162 are illustrated in FIGS. 1H′ and 1H″. As shown in FIG. 1H′, in some examples the formation of the lower portion 164 of the gate electrode structure 162 can include flanges 165 that extend over corresponding flanges of dielectric layer 160 and over a portion of the polish stop layer 140. This feature can, in some cases, be created by variations in patterning and deposition processes.

FIG. 1H″ illustrates details regarding field plates 168 extending laterally from the upper portion 166 of the gate electrode structure 162, much like wings or extensions. In particular, the field plates have a width D1 and a height D2 that in some examples have dimensions relative to one another in any of the following ranges (D1:D2): from 2:1 to 10:1; from 2:1 to 5:1; from 5:1 to 10:1; from 2:1 to 4:1. In some examples, the dimension D1 is configured to manage the added capacitance of having this structure integrated into the gate electrode structure 162, and in particular, configured so as to minimize capacitance induced in or by adjacent conductive structures (e.g., source/drain contacts).

FIG. 1I illustrates an example device 180 that includes the features previously described and that also includes source/drain electrical contacts 170A, 170B, respectively. These can be formed, for instance, by first depositing and planarizing additional insulator material, so as to provide a surface suitable for any further processing. Then, contact trenches can then be etched through that additional insulator material, over the source/drain regions and through any intervening layers using wet etches, dry etches, and/or combinations thereof. The trenches can then be filled with contact materials using any of a variety of deposition methods. Example source drain contact materials include, for example, tungsten, titanium, silver, gold, aluminum, copper, cobalt, and alloys thereof. The contacts may include multiple layers, such as work function tuning layers, resistance-reducing layers, and capping layers.

It will be appreciated that materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer.

Example System

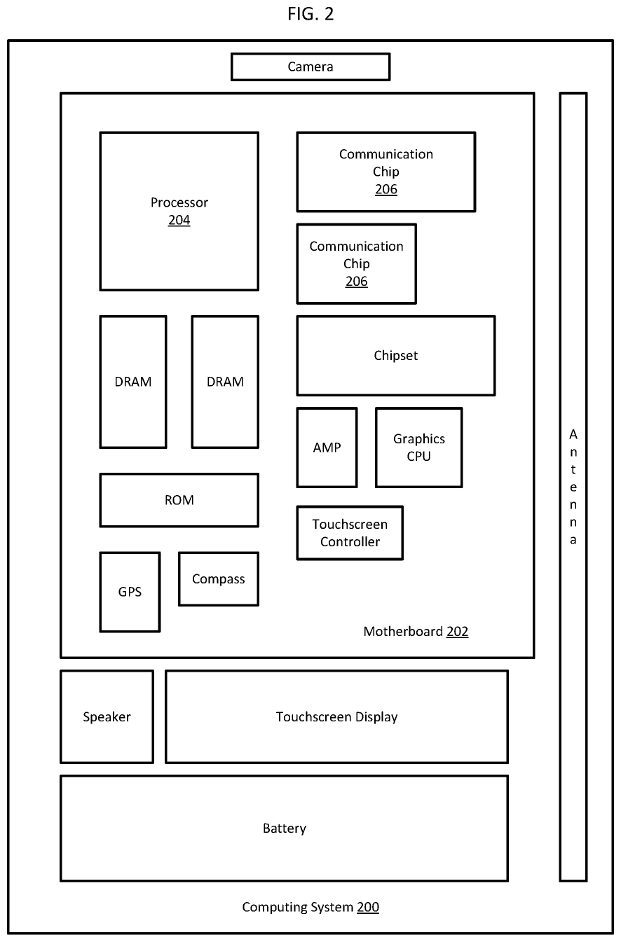

FIG. 2 is an example computing system implemented with one or more of the integrated circuit structures as disclosed herein, in accordance with some embodiments of the present disclosure. As can be seen, the computing system 200 houses a motherboard 202. The motherboard 202 may include a number of components, including, but not limited to, a processor 204 and at least one communication chip 206, each of which can be physically and electrically coupled to the motherboard 202, or otherwise integrated therein. As will be appreciated, the motherboard 202 may be, for example, any printed circuit board, whether a main board, a daughterboard mounted on a main board, or the only board of system 200, etc.

Depending on its applications, computing system 200 may include one or more other components that may or may not be physically and electrically coupled to the motherboard 202. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 200 may include one or more integrated circuit structures or devices configured in accordance with an example embodiment (e.g., to include one or more T-shaped gate electrodes with integral field plates, as variously provided herein). In some embodiments, multiple functions can be integrated into one or more chips (e.g., for instance, note that the communication chip 206 can be part of or otherwise integrated into the processor 204).

The communication chip 206 enables wireless communications for the transfer of data to and from the computing system 200. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 206 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 200 may include a plurality of communication chips 206. For instance, a first communication chip 206 may be dedicated to shorter range wireless communications such as Wi-Fi and Bluetooth and a second communication chip 206 may be dedicated to longer range wireless communications such as GPS, EDGE, GPRS, CDMA, WiMAX, LTE, Ev-DO, and others. In some embodiments, communication chip 206 may include one or more transistor structures having a gate stack an access region polarization layer as variously described herein.

The processor 204 of the computing system 200 includes an integrated circuit die packaged within the processor 204. In some embodiments, the integrated circuit die of the processor includes onboard circuitry that is implemented with one or more integrated circuit structures or devices as variously described herein. The term “processor” may refer to any device or portion of a device that processes, for instance, electronic data from registers and/or memory to transform that electronic data into other electronic data that may be stored in registers and/or memory.

The communication chip 206 also may include an integrated circuit die packaged within the communication chip 206. In accordance with some such example embodiments, the integrated circuit die of the communication chip includes one or more integrated circuit structures or devices as variously described herein. As will be appreciated in light of this disclosure, note that multi-standard wireless capability may be integrated directly into the processor 204 (e.g., where functionality of any chips 206 is integrated into processor 204, rather than having separate communication chips). Further note that processor 204 may be a chip set having such wireless capability. In short, any number of processor 204 and/or communication chips 206 can be used. Likewise, any one chip or chip set can have multiple functions integrated therein.

In various implementations, the computing system 200 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

### FURTHER EXAMPLE EMBODIMENTS

The following examples pertain to further embodiments, from which numerous permutations and configurations will be apparent.

Example 1 is an integrated circuit structure comprising: a source region and a drain region; a semiconductor body between the source region and the drain region, the semiconductor body comprising a semiconductor material having a band gap of at least 3.0 eV; and a gate structure over the semiconductor body, the gate structure comprising a first portion between the source region and the drain region, the first portion having a first width, and a second portion over and connected to the first portion, the second portion having a second width greater than the first width, wherein the second portion of the gate structure further comprises at least one extension extending laterally therefrom.

Example 2 includes the subject matter of Example 1, wherein: the first portion has a first height; the second portion has a second height; and the at least one extension has a third height less than the second height and less than the first height.

Example 3 includes the subject matter of Example 1 or 2, wherein: the at least one extension has a third width greater than the second width; and the third width is at least three times greater than the third height.

Example 4 includes the subject matter of any of the preceding Examples, wherein the first portion, the second portion, and the at least one extension comprise a conductive material.

Example 5 includes the subject matter of any of the preceding Examples, wherein the source region and the drain region comprise nitrogen and one or both of indium and gallium.

Example 6 includes the subject matter of any of the preceding Examples, wherein the semiconductor material of the semiconductor body is a III/V semiconductor material.

Example 7 includes the subject matter of any of the preceding Examples, wherein the semiconductor material of the semiconductor body comprises gallium and nitrogen.

Example 8 includes the subject matter of Example 7, wherein the semiconductor material of the semiconductor body further comprises one or both of indium and aluminum.

Example 9 includes the subject matter of any of the preceding Examples, further comprising one or more dielectric layers between the first portion of the gate structure and both of the source region and the drain region.

Example 10 includes the subject matter of any of the preceding Examples, further comprising a semiconductor layer over the semiconductor body, and an insulation layer over the semiconductor layer, the semiconductor layer comprising nitrogen and one or both of aluminum and gallium, both of the semiconductor layer and the insulation layer also between the source region and the drain region.

Example 11 includes the subject matter of any of the preceding Examples, further comprising a layer between the semiconductor body and a substrate that has a first lattice parameter that 17% or less different from a second lattice parameter of the semiconductor body.

Example 12 includes the subject matter of Example 11, wherein the layer between the semiconductor body and the substrate comprises aluminum and nitrogen.

Example 13 includes the subject matter of Example 11, wherein the substrate is (111) silicon.

Example 14 includes the subject matter of any of the preceding Examples, wherein a top of the first portion of the gate structure adjacent to the second portion of the gate structure has an extension with a width that is greater than the first width and less than the second width.

Example 15 is an integrated circuit device comprising the integrated circuit structure of any of the preceding Examples.

Example 16 is a printed circuit board comprising the integrated circuit structure of any of the preceding Examples.

Example 17 is an electronic system comprising the integrated circuit structure of any of the preceding Examples.

Example 18 is an integrated circuit structure comprising: a source region and a drain region; a semiconductor body between the source region and the drain region, the semiconductor body comprising gallium and nitrogen; and a gate structure over the semiconductor body, the gate structure comprising a first portion between the source region and the drain region, the first portion having a first width, a second portion over and connected to the first portion, the second portion having a second width greater than the first width, and at least one conductive structure extending laterally from the second portion.

Example 19 includes the subject matter of Example 18, wherein the at least one conductive structure extends laterally over one or more of the source region and the drain region.

Example 20 includes the subject matter of either of Examples 18 or 19, wherein the at least one conductive structure has a third width greater than the first width and greater than the second width.

Example 21 includes the subject matter of Example 21, wherein the at least one conductive structure has a height, the third width at least three times greater than the height.

Example 22 includes the subject matter of any of Examples 18-21, wherein the source region and the drain region comprise two or more of indium, gallium, and nitrogen.

Example 23 is an integrated circuit device comprising the integrated circuit structure of any of

Example 24 is a printed circuit board comprising the integrated circuit structure of any of Examples 18-23.

Example 25 is an electronic system comprising the integrated circuit structure of any of Examples 18-24.

Example 26 is an integrated circuit structure comprising: a source region and a drain region; a semiconductor body between the source region and the drain region, the semiconductor body comprising a semiconductor material having a bandgap of at least 3.0 eV; and a gate structure over the semiconductor body, the gate structure comprising a central portion over the semiconductor body having a first width and a first height, and plates extending laterally from the central portion, the plates having a second width greater than the first width and a second height less than the first height.

Example 27 includes the subject matter of Example 26, further comprising a lower portion of the gate structure between the central portion and the semiconductor body, the lower portion having a third width less than the first width.

Example 28 includes the subject matter of either of Example 26 or Example 27, wherein the central portion and the plates comprise a conductive material.

Example 29 includes the subject matter of any of Examples 26-28, wherein the source region and the drain region comprise two or more of indium, gallium, and nitrogen.

Example 30 includes the subject matter of any of Examples 26-29, wherein the semiconductor material of the semiconductor body is a III/V semiconductor material.

Example 31 includes the subject matter of any of Examples 26-30, wherein the semiconductor material of the semiconductor body comprises gallium and nitrogen.

Example 32 includes the subject matter of Example 31, wherein the semiconductor material of the semiconductor body further comprises indium and aluminum.

Example 33 is an integrated circuit device comprising the integrated circuit structure of any of Examples 26-32.

Example 34 is a printed circuit board comprising the integrated circuit structure of any of Examples 26-33.

Example 35 is an electronic system comprising the integrated circuit structure of any of Examples 26-34.

What is claimed is:

1. An integrated circuit structure comprising:
a source region and a drain region;
a semiconductor body between the source region and the drain region, the semiconductor body comprising a semiconductor material having a band gap of at least 3.0 eV; and
a gate structure over the semiconductor body, the gate structure comprising
a first portion between the source region and the drain region, the first portion having a first width, and
a second portion over and connected to the first portion, the second portion having a second width greater than the first width,
wherein the second portion of the gate structure further comprises at least one extension extending laterally therefrom.

2. The integrated circuit structure of claim 1, wherein:
the first portion has a first height;
the second portion has a second height; and
the at least one extension has a third height less than the second height and less than the first height.

3. The integrated circuit structure of claim 2, wherein:
the at least one extension has a third width greater than the second width; and
the third width is at least three times greater than the third height.

4. The integrated circuit structure of claim 1, wherein the source region and the drain region comprise nitrogen and one or both of indium and gallium.

5. The integrated circuit structure of claim 1, wherein the semiconductor material of the semiconductor body comprises gallium and nitrogen.

6. The integrated circuit structure of claim 5, wherein the semiconductor material of the semiconductor body further comprises one or both of indium and aluminum.

7. The integrated circuit structure of claim 1, wherein a top of the first portion of the gate structure adjacent to the second portion of the gate structure has an extension with a width that is greater than the first width and less than the second width.

8. An integrated circuit device comprising the integrated circuit structure of claim 1.

9. A printed circuit board comprising the integrated circuit structure of claim 1.

10. An electronic system comprising the integrated circuit structure of claim 1.

11. An integrated circuit structure comprising:
a source region and a drain region;
a semiconductor body between the source region and the drain region, the semiconductor body comprising gallium and nitrogen; and
a gate structure over the semiconductor body, the gate structure comprising
a first portion between the source region and the drain region, the first portion having a first width,
a second portion over and connected to the first portion, the second portion having a second width greater than the first width, and
at least one conductive structure extending laterally from the second portion.

12. The integrated circuit structure of claim 11, wherein the at least one conductive structure extends laterally over one or more of the source region and the drain region.

13. The integrated circuit structure of claim 11, wherein the at least one conductive structure has a third width greater than the first width and greater than the second width.

14. The integrated circuit structure of claim 13, wherein the at least one conductive structure has a height, the third width at least three times greater than the height.

15. An electronic system comprising the integrated circuit structure of claim 11.

16. An integrated circuit structure comprising:
a source region and a drain region;
a semiconductor body between the source region and the drain region, the semiconductor body comprising a semiconductor material having a band gap of at least 3.0 eV; and
a gate structure over the semiconductor body, the gate structure comprising
a central portion over the semiconductor body having a first width and a first height, and
plates extending laterally from the central portion, the plates having a second width greater than the first width and a second height less than the first height.

17. The integrated circuit structure of claim 16, further comprising a lower portion of the gate structure between the central portion and the semiconductor body, the lower portion having a third width less than the first width.

18. The integrated circuit structure of claim 16, wherein the source region and the drain region comprise two or more of indium, gallium, and nitrogen.

19. The integrated circuit structure of claim 16, wherein the semiconductor material of the semiconductor body comprises gallium and nitrogen.

20. An electronic system comprising the integrated circuit structure of claim 16.
